(19) United States
(12) Patent Application Publication
(10) Pub. No.: US 2021/0364609 A1
(43) Pub. Date: Nov. 25, 2021

(54) SCANNING MIRROR MECHANISMS FOR LIDAR SYSTEMS, AND RELATED METHODS AND APPARATUS

(71) Applicant: VELODYNE LIDAR USA, INC., San Jose, CA (US)

(72) Inventors: David S. Hall, Oakland, CA (US); Andrew Janik, San Jose, CA (US); Mathew Noel Rekow, Santa Cruz, CA (US); Anand Gopalan, Foster City, CA (US); Stephen S. Nestinger, Fremont, CA (US); William B. Etheridge, San Mateo, CA (US)

(21) Appl. No.: 17/392,080

(22) Filed: Aug. 2, 2021

Related U.S. Application Data
(63) Continuation-in-part of application No. PCT/US2021/070566, filed on May 14, 2021.
(60) Provisional application No. 63/025,138, filed on May 14, 2020.

(51) Int. Cl. G01S 7/481; G02B 26/10; G01S 17/89; G01R 33/00

(52) U.S. Cl. CPC G01S 7/4817; G01R 33/0017; G01S 17/89; G02B 26/105

(57) ABSTRACT

A scanner of a LiDAR system includes a mirror configured to redirect a light signal emitted by an optical emitter, a first axis scanning system configured to rotate the mirror about a first axis and with respect to the optical emitter, that controls a first angle of emission of the light signal from the LiDAR system into a field of view of the LiDAR system, and a second axis scanning system configured to rotate the mirror about a second axis and with respect to the optical emitter, that controls a second angle of emission of the light signal from the LiDAR system into the field of view. The first axis scanning mechanism is configured to rotate the reflective surface of the mirror at least 45 degrees about the first axis.

### CROSS-REFERENCE TO RELATED APPLICATIONS

This application is a continuation-in-part of International Application No. PCT/US2021/070566, titled SCANNING MIRROR MECHANISMS FOR LIDAR SYSTEMS, AND RELATED METHODS AND APPARATUS and filed on May 14, 2021 (Attorney Docket No. VLI-047WO), which claims priority to and benefit of U.S. Provisional Patent Application Ser. No. 63/025,138, titled 3D LIDAR WITH SCANNING MIRROR MECHANISM and filed on May 14, 2020 (Attorney Docket No. VLI-047PR), each of which is hereby incorporated by reference herein in its entirety.

### FIELD OF TECHNOLOGY

The present disclosure relates generally to light detection and ranging (“LiDAR”) technology and, more particularly, to LiDAR-based 3D point cloud measuring systems and methods including a scanning mirror mechanism.

### BACKGROUND

Light detection and ranging (“LiDAR”) systems measure the attributes of their surrounding environments (e.g., shape of a target, contour of a target, distance to a target, etc.) by illuminating the target with pulsed laser light and measuring the reflected pulses with sensors. Differences in laser return times and wavelengths can then be used to make digital, three-dimensional (“3D”) representations of a surrounding environment. LiDAR technology may be used in various applications including autonomous vehicles, advanced driver assistance systems, mapping, security, surveying, robotics, geology and soil science, agriculture, unmanned aerial vehicles, airborne obstacle detection (e.g., obstacle detection systems for aircraft), and so forth. Depending on the application and associated field of view (FOV), multiple channels or laser beams may be used to produce images in a desired resolution. A LiDAR system with greater numbers of channels can generally generate larger numbers of pixels.

In a conventional multi-channel LiDAR device, optical transmitters are paired with optical receivers to form multiple “channels.” In operation, each channel's transmitter emits an optical (e.g., laser) illumination signal into the device's environment and each channel's receiver detects the portion of the return signal that is reflected back to the receiver by the surrounding environment. In this way, each channel provides “point” measurements of the environment, which can be aggregated with the point measurements provided by the other channel(s) to form a “point cloud” of measurements of the environment.

Advantageously, the measurements collected by any LiDAR channel may be used, inter alia, to determine the distance (i.e., “range”) from the device to the surface in the environment that reflected the channel's transmitted optical signal back to the channel's receiver. The range to a surface may be determined based on the time of flight (TOF) of the channel's signal (e.g., the time elapsed from the transmitter's emission of the optical (e.g., illumination) signal to the receiver's reception of the return signal reflected by the surface).

In some instances, LiDAR measurements may also be used to determine the reflectance of the surface that reflects an optical (e.g., illumination) signal. The reflectance of a surface may be determined based on the intensity on the return signal, which generally depends not only on the reflectance of the surface but also on the range to the surface, the emitted signal's glancing angle with respect to the surface, the power level of the channel's transmitter, the alignment of the channel's transmitter and receiver, and other factors.

### SUMMARY

According to an aspect of the present disclosure, a scanner of a LiDAR system includes a mirror having a reflective surface configured to redirect a light signal emitted by an optical emitter; a first axis scanning system configured to rotate the reflective surface of the mirror about a first axis and with respect to the optical emitter, that controls a first angle of emission of the light signal from the LiDAR system into a field of view of the LiDAR system; and a second axis scanning system configured to rotate the reflective surface of the mirror about a second axis and with respect to the optical emitter, that controls a second angle of emission of the light signal from the LiDAR system into the field of view of the LiDAR system. The first axis scanning mechanism is configured to rotate the reflective surface of the mirror at least 45 degrees about the first axis.

### BRIEF DESCRIPTION OF THE DRAWINGS

The accompanying figures, which are included as part of the present specification, illustrate the presently preferred embodiments and together with the general description given above and the detailed description of the preferred embodiments given below serve to explain and teach the principles described herein.

FIG. 1 shows an illustration of a LiDAR system, in accordance with some embodiments.

FIG. 2A shows an illustration of the operation of a LiDAR system, in accordance with some embodiments.

FIG. 2B shows an illustration of optical components of a channel of a LiDAR system, in accordance with some embodiments.

FIG. 3A illustrates a side view of a first axis of an exemplary scanning mirror system, in accordance with some embodiments. FIG. 3B illustrates an isometric view of the first axis of the exemplary scanning mirror system of FIG. 3A.

FIG. 4A illustrates an isometric view of a second axis of an exemplary scanning mirror system, according to some embodiments. FIG. 4B illustrates a side view of the second axis of the exemplary scanning mirror system of FIG. 4A.

FIG. 5 illustrates another embodiment of a scanning mirror system.

FIGS. 6A, 6B, and 6C illustrate various views of an exemplary first axis for a scanning mirror system, according to some embodiments.

FIG. 6D illustrates another embodiment of a first axis of an exemplary scanning mirror system.

FIG. 7 illustrates the operation of an exemplary scanning mirror, according to some embodiments.

FIG. 8 illustrates a side view of a scanning mirror system having the first axis of FIGS. 3A-3B and second axis of FIGS. 4A-4B.

FIG. 9 illustrates a side view of the scanning mirror system of FIG. 5.

FIG. 10 illustrates a perspective view of another embodiment of a scanning mirror system.

FIG. 11 illustrates a cross-sectional view of another embodiment of a second axis of an exemplary scanning mirror system.

FIG. 12 illustrates a perspective view of a scanning mirror system having the second axis of FIG. 11, according to some embodiments.

FIG. 13 illustrates a side view of the scanning mirror system of FIG. 11, according to some embodiments.

FIG. 14 illustrates a perspective view of another scanning mirror system having the second axis of FIG. 11, according to some embodiments.

FIG. 15 provides an example of a Raster scan to illustrate the movement of the scanning mirror mechanism.

FIG. 16A is a plot of the angle of exemplary traces (described above) as a function of time. FIG. 16B is a plot of the angle of an exemplary laser trace for an experimental setup of the scanning mirror system.

FIGS. 17A-17B illustrate two views of an exemplary scanning pattern for an exemplary scanning mirror.

FIG. 18 shows a block diagram of a computing device/information handling system, in accordance with some embodiments.

While the present disclosure is subject to various modifications and alternative forms, specific embodiments thereof have been shown by way of example in the drawings and will herein be described in detail. The present disclosure should not be understood to be limited to the particular forms disclosed, but on the contrary, the intention is to cover all modifications, equivalents, and alternatives falling within the spirit and scope of the present disclosure.

### DETAILED DESCRIPTION

Disclosed herein are various exemplary embodiments of a 3D point cloud measuring system and method. The exemplary measuring system can include a scanning mirror system (e.g., instead of a rotating assembly). The scanning mirror(s) can have a first axis and a second axis. As used herein, the first axis may be referred to as the “fast” axis and the second axis may be referred to as the “slow” axis. The scanning mirror mechanism can be controlled to emit and detect photons to create a 3-D point cloud.

### Terminology

Measurements, sizes, amounts, etc. may be presented herein in a range format. The description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as 10-20 meters should be considered to have specifically disclosed subranges such as 10-11 meters, 10-12 meters, 10-13 meters, 10-14 meters, 11-12 meters, 11-13 meters, etc.

Furthermore, connections between components or systems within the figures are not intended to be limited to direct connections. Rather, data or signals between these components may be modified, re-formatted, or otherwise changed by intermediary components. Also, additional or fewer connections may be used. The terms “coupled,” “connected,” or “communicatively coupled” shall be understood to include direct connections, indirect connections through one or more intermediary devices, wireless connections, and so forth.

Reference in the specification to “one embodiment,” “preferred embodiment,” “an embodiment,” “some embodiments,” or “embodiments” means that a particular feature, structure, characteristic, or function described in connection with the embodiment is included in at least one embodiment of the invention and may be in more than one embodiment. Also, the appearance of the above-noted phrases in various places in the specification is not necessarily referring to the same embodiment or embodiments.

The use of certain terms in various places in the specification is for illustration purposes only and should not be construed as limiting. A service, function, or resource is not limited to a single service, function, or resource; usage of these terms may refer to a grouping of related services, functions, or resources, which may be distributed or aggregated.

Furthermore, one skilled in the art shall recognize that: (1) certain steps may optionally be performed; (2) steps may not be limited to the specific order set forth herein; (3) certain steps may be performed in different orders; and (4) certain steps may be performed simultaneously or concurrently.

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements).

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of” “only one of” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements).

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

### Some Examples of LiDAR Systems

A light detection and ranging (“LiDAR”) system may be used to measure the shape and contour of the environment surrounding the system. LiDAR systems may be applied to numerous applications including autonomous navigation and aerial mapping of surfaces. In general, a LiDAR system emits light (e.g., illumination) pulses (e.g., laser pulses) that are subsequently reflected by objects within the environment in which the system operates. The time each pulse travels from being emitted to being received (i.e., time-of-flight) may be measured to determine the distance between the LiDAR system and the object that reflects the pulse. The science of LiDAR systems is based on the physics of light and optics.

In a LiDAR system, light may be emitted from a rapidly firing laser. Laser light travels through a medium and reflects off points of surfaces in the environment (e.g., surfaces of buildings, tree branches, vehicles, etc.). The reflected light energy returns to a LiDAR detector where it may be recorded and used to map the environment.

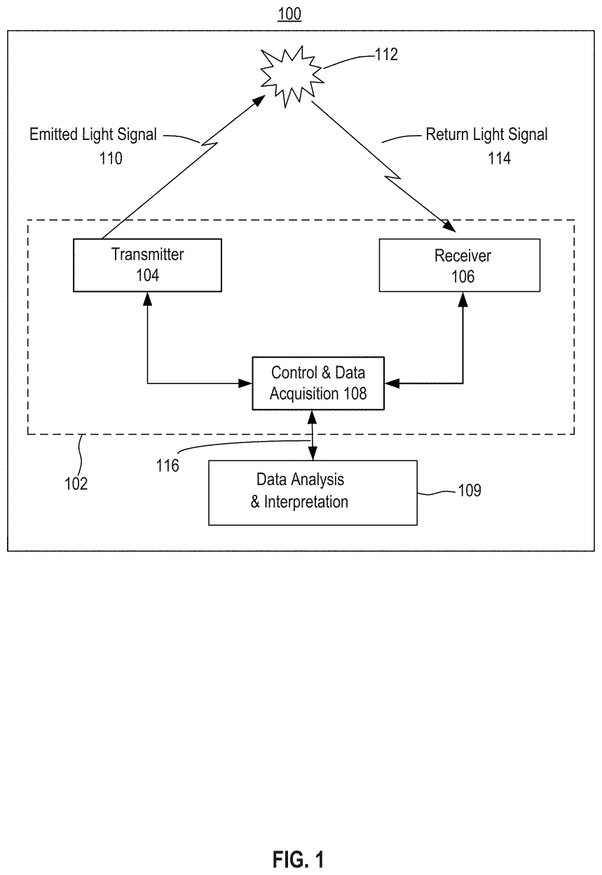

FIG. 1 depicts the operation of the medium- and long-range portion of an exemplary LiDAR system 100, according to some embodiments. In the example of FIG. 1, the LiDAR system 100 includes a LiDAR device 102, which may include a transmitter 104 that is configured to generate and transmit an emitted light signal 110, a receiver 106 that is configured to detect a return light signal 114, and a control & data acquisition module 108. The transmitter 104 may include a light source (e.g., laser), electrical components operable to activate (“drive”) and deactivate the light source in response to electrical control signals, and optical components adapted to shape and redirect the light emitted by the light source. The receiver 106 may include an optical detector (e.g., photodiode) and optical components adapted to shape return light signals 114 and direct those signals to the detector. In some implementations, one or more of optical components (e.g., lenses, mirrors, etc.) may be shared by the transmitter and the receiver. The LiDAR device 102 may be referred to as a LiDAR transceiver or “channel.” In operation, the emitted light signal 110 propagates through a medium and reflects off an object(s) 112, whereby a return light signal 114 propagates through the medium and is received by receiver 106.

The control & data acquisition module 108 may be adapted to control the light emission by the transmitter 104 and may record data derived from the return light signal 114 detected by the receiver 106. In some embodiments, the control & data acquisition module 108 is further adapted to control the power level at which the transmitter 104 operates when emitting light. For example, the transmitter 104 may be configured to operate at a plurality of different power levels, and the control & data acquisition module 108 may select the power level at which the transmitter 104 operates at any given time. Any suitable technique may be used to control the power level at which the transmitter 104 operates. In some variations, the control & data acquisition module 108 may be adapted to determine (e.g., measure) particular characteristics of the return light signal 114 detected by the receiver 106. For example, the control & data acquisition module 108 may be configured to measure the intensity of the return light signal 114 using any suitable technique.

A LiDAR transceiver 102 may include one or more optical lenses and/or mirrors (not shown) to transmit and shape the emitted light signal 110 and/or to redirect and shape the return light signal 114. For example, the transmitter 104 may emit a laser beam having a plurality of pulses in a particular sequence. Design elements of the receiver 106 may include its horizontal field of view (hereinafter, “FOV”) and its vertical FOV. One skilled in the art will recognize that the FOV parameters effectively define the visibility region relating to the specific LiDAR transceiver 102. More generally, the horizontal and vertical FOVs of a LiDAR system 100 may be defined by a single LiDAR device (e.g., sensor) or may relate to a plurality of configurable sensors (which may be exclusively LiDAR sensors or may have different types of sensors). The FOV may be considered a scanning area for a LiDAR system 100. A scanning mirror may be utilized to obtain a scanned FOV.

In some implementations, the LiDAR system 100 may also include or may be electronically coupled to a data analysis & interpretation module 109, which may be adapted to receive output (e.g., via connection 116) from the control & data acquisition module 108 and, moreover, to perform data analysis functions on, for example, return signal data. The connection 116 may be implemented using a wireless or non-contact communication technique.

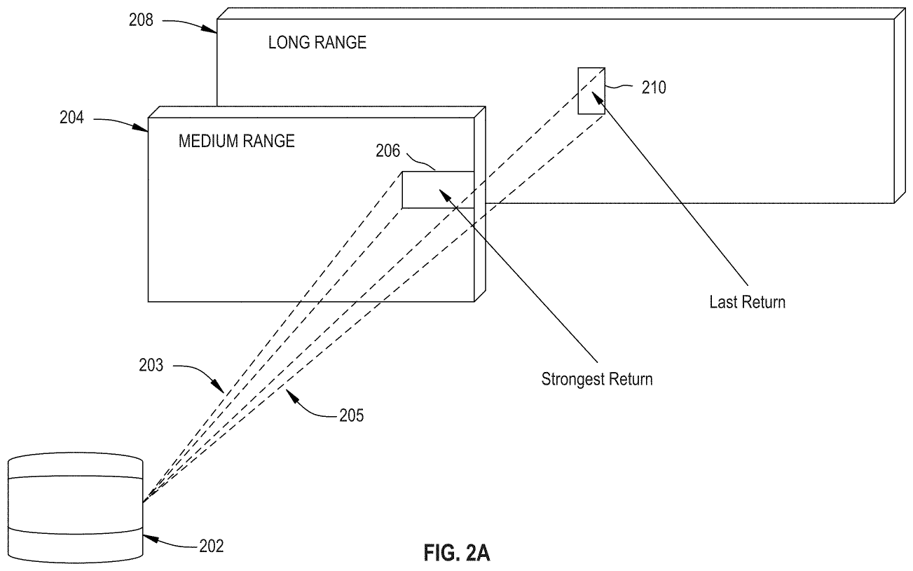

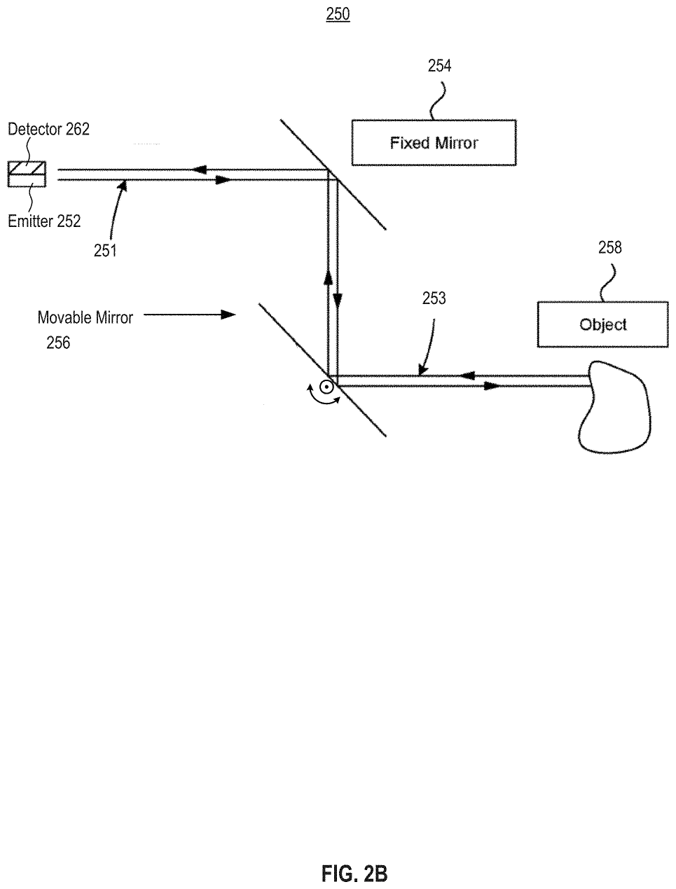

FIG. 2A illustrates the operation of the medium- and long-range portion(s) of a LiDAR system 202, in accordance with some embodiments. In the example of FIG. 2A, two return light signals 203 and 205 are shown, corresponding to medium-range and long-range return signals. Laser beams generally tend to diverge as they travel through a medium. Due to the laser's beam divergence, a single laser emission may hit multiple objects at different ranges from the LiDAR system 202, producing multiple return signals 203, 205. The LiDAR system 202 may analyze multiple return signals 203, 205 and report one of the return signals (e.g., the strongest return signal, the last return signal, etc.) 203, 205 or more than one (e.g., all) of the return signals 203, 205. In the illustrative example shown in FIG. 2A, LiDAR system 202 emits a laser beam in the direction of medium-range wall 204 and long-range wall 208. As illustrated, the majority of the emitted beam hits the medium-range wall 204 at area 206 resulting in a (e.g., medium-range) return signal 203, and another portion of the emitted beam hits the long-range wall 208 at area 210 resulting in a (e.g., long-range) return signal 205. Return signal 203 may have a shorter TOF and a stronger received signal strength compared with return signal 205. In both single- and multiple-return LiDAR systems 202, it is important that each return signal 203, 205 is accurately associated with the transmitted (e.g., illumination) light signal so that an accurate TOF may be calculated.

Some embodiments of a LiDAR system may capture distance data in a (e.g., single plane) two-dimensional (2D) point cloud manner. These LiDAR systems may be used in industrial applications, or for surveying, mapping, autonomous navigation, and other uses. Some embodiments of these systems rely on the use of a single laser emitter/detector pair combined with a moving mirror to effect scanning across at least one plane. This mirror may reflect the emitted light from the transmitter (e.g., laser diode), and/or may reflect the return light to the detector. Use of a movable mirror in this manner may enable the LiDAR system to achieve 5-360 degrees of azimuth (horizontal) view while simplifying both the system design and manufacturability. In some embodiments, the movable mirror may be an oscillating mirror that scans in at least one direction (e.g., horizontally or vertically) by oscillating on an axis. The oscillation may provide the LiDAR system with 5-180 degrees (e.g., 5-120 degrees, 15-120 degrees, 70 degrees, 90 degrees, or 120 degrees) of view in the direction scanned via the mirror's oscillation. Many applications require more data than just a single (e.g., 2D) plane. The 2D point cloud, however, may be expanded to form a 3D point cloud, in which multiple 2D point clouds are used, each pointing at a different elevation (i.e., vertical) angle. Design elements of the receiver of the LiDAR system 202 may include the horizontal FOV and the vertical FOV.

FIG. 2B depicts a set of optical components 250 of a channel 102 of a LiDAR system 100 according to some embodiments. In the example of FIG. 2B, the LiDAR channel 102 uses a single emitter 252/detector 262 pair combined with a fixed mirror 254 and a movable mirror 256 to effectively scan across a plane. Distance measurements obtained by such a system may be effectively two-dimensional (e.g., planar), and the captured distance points may be rendered as a 2D (e.g., single plane) point cloud. In some embodiments, but without limitation, the movable mirror 256 may oscillate at very fast speeds (e.g., thousands of cycles per minute).

The emitted laser signal 251 may be directed to a fixed mirror 254, which may reflect the emitted laser signal 251 to the movable mirror 256. As movable mirror 256 moves (e.g., oscillates), the emitted laser signal 251 may reflect off an object 258 in its propagation path. The reflected return signal 253 may be coupled to the detector 262 via the movable mirror 256 and the fixed mirror 254. Design elements of the LiDAR system 250 include the horizontal FOV and the vertical FOV, which define a scanning area.

### Some Embodiments of a Scanning Mirror Mechanism for a LiDAR System

The scanning mirror is used to control the location at which the photons are transmitted and detected in order to create a 3D point cloud. This eliminates the need for a typical rotary motor, thus, reduces the need for bearings or other friction causing mechanisms. This allows for reduced cost, wear, and energy required to drive the LIDAR system.

The mirror is rotationally oscillated electromagnetically in order to control the mirror's rotation on one or more axes. The scanning mirror mechanism includes a mirror, magnets, coils, structures, position/rotation sensors, and flexures. The flexure can be made of thin metal or a bundle of wires (e.g., parallel wires) (e.g., non-twisted parallel wires), which is structurally fixed at two ends and allowed to twist with the mirror and mirror mechanisms.

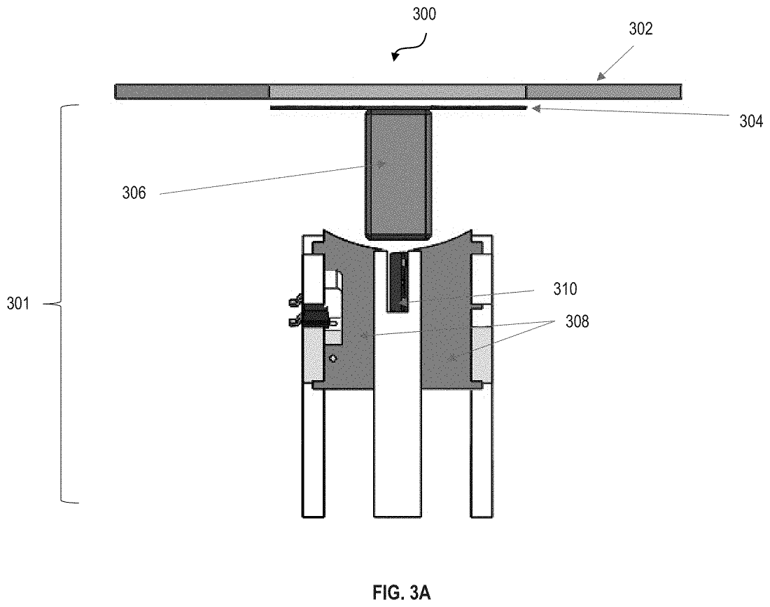

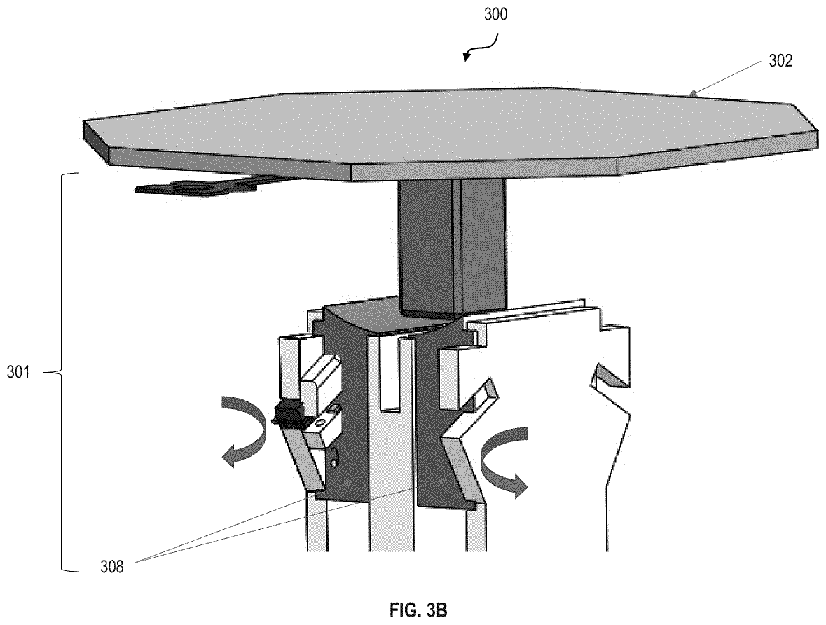

FIGS. 3A-3B illustrate the first (or fast) axis 301 of an exemplary scanning mirror system 300. The scanning mirror system 300 may include the fast axis 301 and a scanning mirror 302. The width of the scanning mirror 302 may be, for example, between 12 mm and 30 mm. The fast axis 301 can include a flexure 304, a magnet 306, one or two coils 308, and a sensor 310. The coils 308 may be copper wound coils.

FIG. 3B illustrates the winding direction of the coils 308. The sensor 310 may be a Hall effect sensor. A Hall effect sensor (or “Hall sensor”) may detect the presence of a magnetic field and measure its magnitude using the Hall Effect. The output voltage of a Hall effect sensor may be proportional (e.g., directly proportional) to the strength of the detected magnetic field. The fast (or first) axis can be configured to operate at the resonant frequency of the system 300 (including the flexure 304, mirror 302, and the magnet 306). Operating at the resonant frequency of the system 300 may reduce (e.g., minimize) the amount of power used by the system 300. In various implementations, the resonant frequency of the system 300 may be a frequency within a range of 5-1000 Hz. The flexure 304 may be affixed (e.g., mounted, glued, etc.) to the mirror 302 and the magnet 306 may be affixed (e.g., mounted, glued, etc.) to the flexure 304.

The flexure 304 can be a thin piece of metal (e.g., spring steel) or a bundle of wires (e.g., parallel or twisted wires) that is designed to twist at a specific frequency depending on the mass of the mirror 302 and magnet 306, and the tension of the flexure 304. In some implementations, the flexure 304 may have a thickness of approximately 0.004 inches or, in the case of a bundle of parallel wires, a diameter of approximately 0.008 inches. There are various ways to tension the flexure(s) 304 including, e.g., a small shaft in a cylinder that has an off-axis shaft, which rotates to create tension, a lever mechanism that includes tightening a screw against a surface to create the tension, and/or elastically bending the flexure holder to install and letting the spring back force be the tensioning mechanism. The flexure 304 of the fast axis of the scanning mirror system having a bundle of wires may provide greater reliability (relative to a thin plate of metal) by resisting fracturing when the mirror 302 rotates over multiple cycles. The flexure 304 may provide improved robustness, especially when the system suffers from a lateral shock, providing improved shock resistance. In some embodiment, bushings are used to tighten the coupling between flexure 304 and other components of the scanning mirror system.

The first axis 301 can be controlled by two coils 308 driven in series that are facing each other. This allows the magnet 306 that is connected to the flexure 304 to move as a pendulum, thus rotationally oscillating the mirror 302, and by facing each other, the coils 308 equalize the magnetic field between the coils, which allows a Hall effect sensor 310 to only detect the position of the magnet 306, and not the coils' magnetic fields. Hall effect sensor(s) 310 and magnet(s) 306 can be used to determine the rotational position of the mirror 302. Other sensors, such as photodiodes, can be used in various implementations as well.

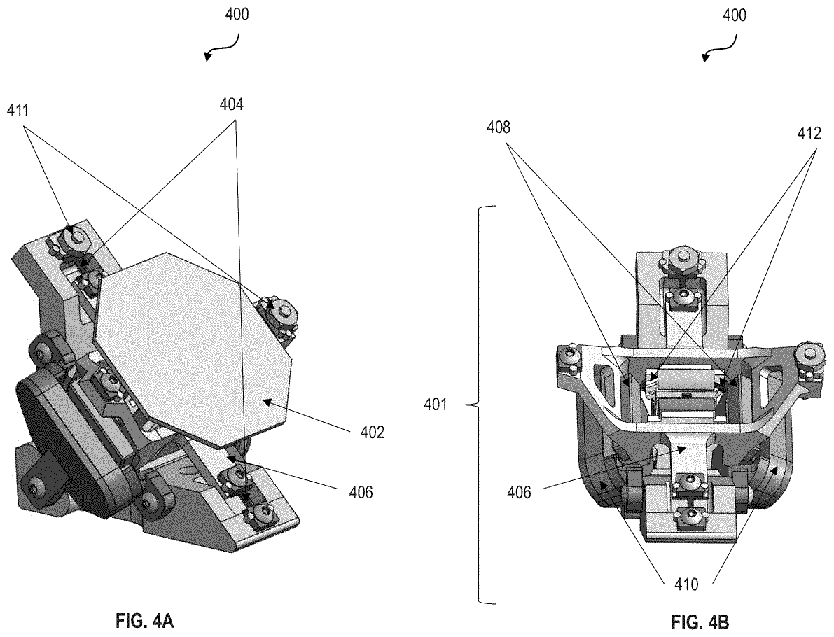

FIGS. 4A-4B illustrate the second (or slow) axis 401 of an exemplary scanning mirror system 400. The scanning mirror system 400 may include the slow axis 401 and a scanning mirror 402. The slow axis 401 can include a tensioning mechanism 411 (e.g., an off-axis cam-type mechanism), flexures 404, and a cradle 406. The flexures 404 may be made of spring steel or a bundle of wires (e.g., parallel wires). In some implementations, the flexures 404 may have a thickness of approximately 0.004 inches or approximately 0.008 inches. The mirror 402 can be disposed in the cradle 406. The width of the scanning mirror 402 may be, for example, between 12 mm and 30 mm.

FIG. 4B illustrates the slow axis 401 of the exemplary scanning mirror system 400 without the mirror 402 present so as to illustrate components behind the mirror 402. The slow axis 401 can include one or more magnets 408 and one or more coils 410 on the second (or slow) axis 401. The system can further include one or more Hall effect sensors 412 for the second (or slow) axis 401. In some configurations, the slow axis 401 may use two Hall sensors 412 to generate a differential signal indicating the strength of the magnetic field generated by the magnet(s) 408. The use of differential sensing may increase the device's resilience to noise.

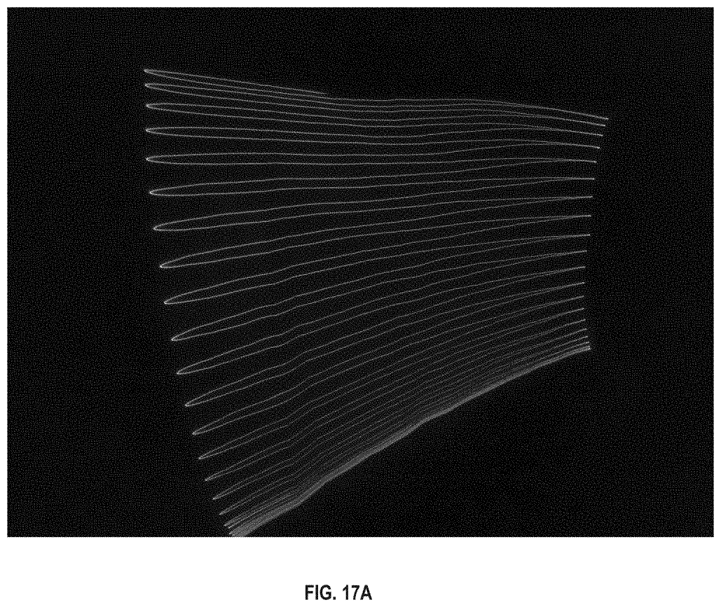

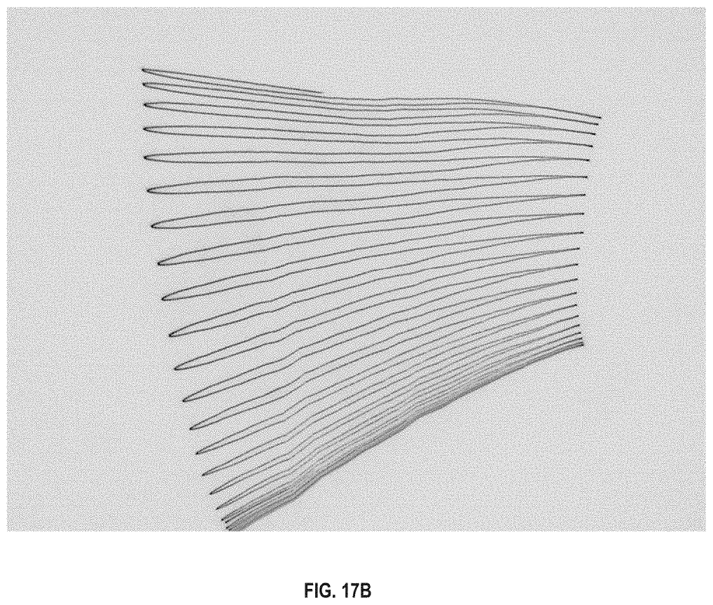

The second (or slow) axis 401 may not be controlled at the resonant frequency of the slow axis 401 or the scanning mirror system 400. The second (or slow) axis 401 can be driven at a determined sequence to create a scan pattern. An example of a scan pattern is shown in FIGS. 17A-17B. The slow axis 401 can be 90° in reference to a fast axis (e.g., fast axis 301) and can include the component(s) of the fast axis. The slow axis 401 may be controlled to synchronize with the fast axis. The slow axis 401 may be driven at a frequency within the range of 0.01-30 Hz. In general, the scan resolution in the direction corresponding to the slow axis may increase as the drive frequency of the slow axis decreases. There are various exemplary implementations for the second (or slow) axis 401.

In a first implementation, the moving components of the slow axis 401 (which has a larger design and lower rotational travel ability) may include a structure (e.g., cradle 406), a magnet 408 on each side of the cradle 406, the mobile components of the fast axis (e.g., flexure 304 and magnet 306), and a flexure 404 connected to each side of the cradle 406 in its axis of rotation. The flexure 404 may be, for example, a bundle of wires. In some embodiments, the flexure 404 is tensioned by the rotation of a shaft. There may be a fixed copper wound coil 410 (2 total) near each of the cradle magnets 408. These coils 410 can be driven in series (e.g., with a frequency between 0.01 Hz and 30 Hz) to rotationally oscillate the cradle 406 and its components.

In another implementation, the moving components of the slow axis 401 (which has a smaller design and greater rotational travel) include a structure (cradle 406), the mobile components of the fast axis (e.g., the flexure 304 and the magnet 306), a flexure 404 connected to each side of the cradle 406 in its axis of rotation, and a copper wound coil on one side of the cradle. The flexure 404 may be, for example, a bundle of wires. In some embodiments, the flexure 404 is tensioned by the rotation of a shaft. There are fixed magnets around the copper wound coil, which allows it to rotate in either direction depending on the direction of the current. In some embodiments, the coil may be driven with an AC signal (e.g., AC current) having a frequency between 0.01 Hz and 30 Hz.

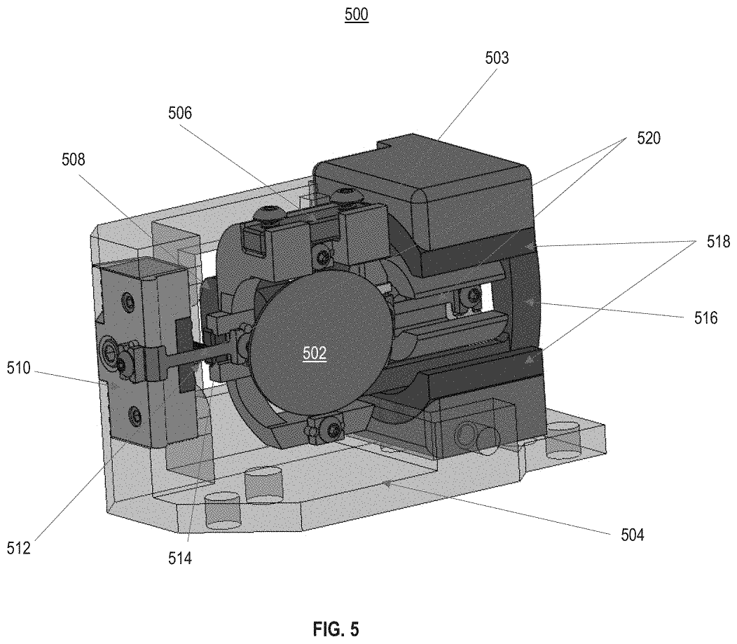

FIG. 5 illustrates an exemplary scanning mirror system 500, which can include fast axis components, slow axis components, a mirror 502 (e.g., scanning mirror), a cradle 503, and a yoke 504. The width (e.g., diameter) of the scanning mirror 502 may be, for example, between 12 mm and 30 mm. The fast axis components may include a tensioner 506 and a coil 508. The slow axis components may include a tensioner 510, sensor 512 (e.g., Hall effect sensor), magnet 514 (e.g., for sensing rotation), coil 516 (e.g., copper wound), magnets 518, and flexure 520. The magnet 514 may be affixed to the cradle 503, such that the magnet 514 rotates with the cradle 503 and the mirror. The sensor 512 may be disposed behind the magnet 514 or adjacent to the magnet 514 along the second axis (e.g., on a circuit board affixed to the yoke 504), such that the sensor 512 can sense the deflection of the magnet 514 (e.g., as described above).

The exemplary flexure 520 may be made of beryllium copper (BeCu). In some implementations, the thickness of the flexure 520 may be approximately 0.003 inches. In some embodiments, the flexure 520 may be or include a bundle of wires (e.g., parallel wires). The diameter of the bundle may be approximately 0.008 inches. In operation, an electrical signal (e.g., voltage and/or current) may be applied to the slow axis coil 516 to control the coil's rotation, which drives the rotation of the scanning mechanism's slow axis (e.g., the vertical axis in FIG. 5). In some embodiments, the electrical signal may be an AC signal (e.g., an AC current) with a frequency between 0.01 Hz and 30 Hz.

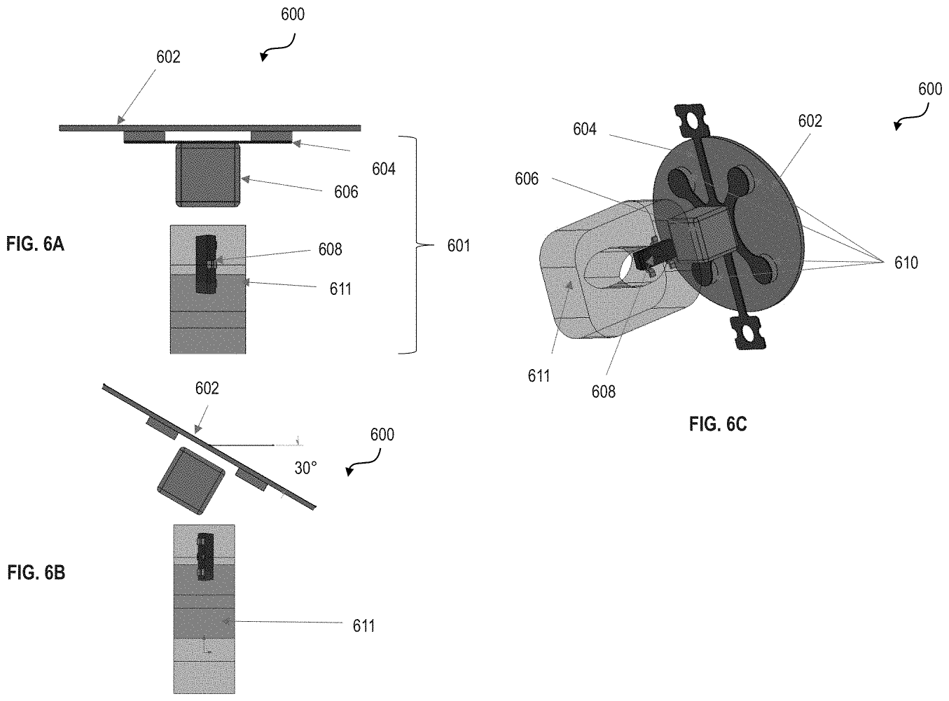

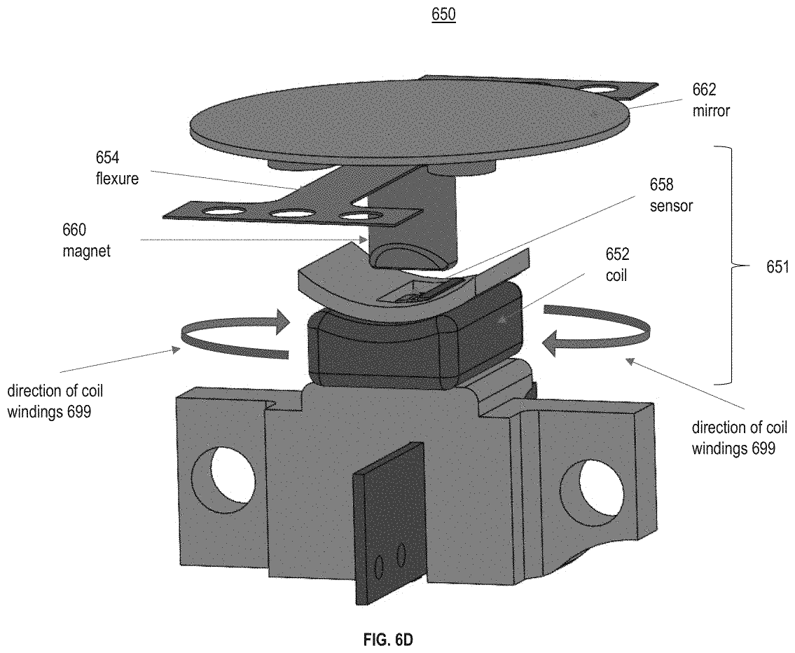

FIGS. 6A-6C illustrate various views of an exemplary fast axis 601 for a scanning mirror system 600. The scanning mirror system 600 may include the fast axis 601 and a scanning mirror 602. The width (e.g., diameter) of the scanning mirror 602 may be, for example, between 12 mm and 30 mm. The exemplary fast axis 601 can include a single coil 611, flexure 604, a magnet 606, and a sensor 608 (e.g., Hall effect sensor). The flexure 604 may be made of spring steel (e.g., of approximately 0.004 inch thickness). Alternatively, the flexure 604 may be or include a bundle of wires (e.g., parallel wires) (e.g., a bundle having a diameter of approximately 0.008 inches). One or more spacers or bushings 610 can be included between the flexure 604 and mirror 602. The Hall effect sensor 608 can sense the magnet 606 and the magnetic field from the coil 611. A controller coupled to the coil 611 can be configured to send a signal to turn off the coil 611 during the time the Hall effect sensor 608 is used to sense the magnet. In some cases, this can occur in a time period on the order of microseconds to nanoseconds. In some implementations, the coil-generated magnetic field can be subtracted from estimations based on testing and experimentation calculations. The resonant frequency of the fast axis 601 can be dependent on the stiffness of the flexure 604 and the total mass and total moment of inertia of the mirror 602, spacer 610, magnet 606, flexure 604, and adhesive. Thus, the resonant frequency of the fast axis 601 may be tuned, for example, by adjusting the stiffness of the flexure 604. In some embodiments, the components of the fast axis of the scanning mirror system 500 of FIG. 5 may include the components of the fast axis 601.

FIG. 6D illustrates an exemplary scanning mirror system 650 having a fast axis 651 having a single coil, according to another embodiment. The fast axis 651 can include a single coil 652, a flexure 654, a magnet 660, and a sensor 658 (e.g., Hall effect sensor). The flexure 654 may be made of spring steel (e.g., of approximately 0.004 inch thickness). Alternatively, the flexure 654 may be or include a bundle of wires (e.g., parallel wires) (e.g., a bundle having a diameter of approximately 0.004-0.008 inches). The width (e.g., diameter) of the scanning mirror 662 may be, for example, between 12 mm and 30 mm. The coil 652 may be wound in the direction 699 indicated in FIG. 6D.

In contrast to the fast axis 600, the Hall effect sensor 658 of the fast axis 650 is positioned within the coil 652. Accordingly, the Hall effect sensor 658 does not sense the magnetic field generated by the power feeding the coil 652. Instead the Hall effect sensor 658 senses changes in the magnetic field generated by magnet 660 without sensing the interference of the coil-generated magnetic field. In contrast, the Hall sensor 608 of the fast axis 600 is positioned mostly above the coil 601. In some embodiments, the components of the fast axis of the scanning mirror system 500 of FIG. 5 may include the components of the fast axis 651.

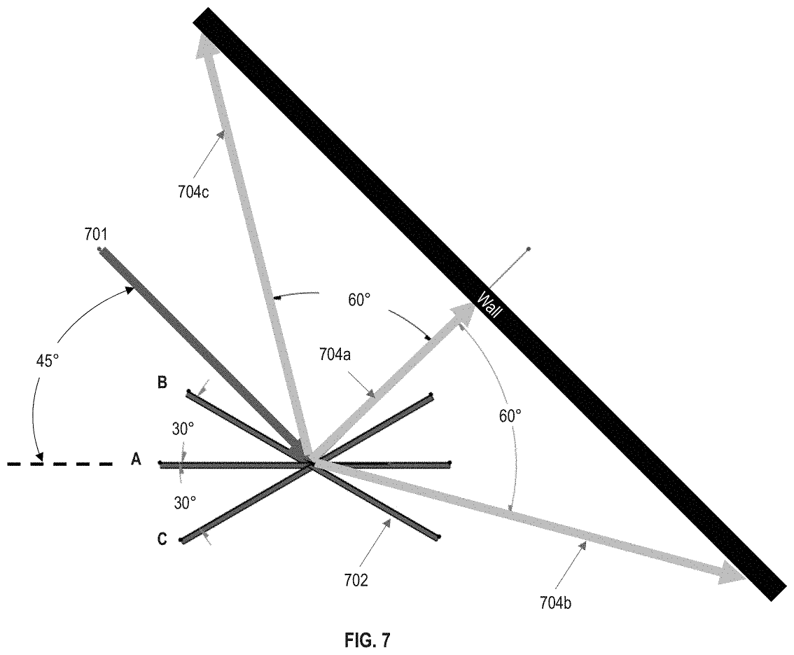

FIG. 7 illustrates the operation of an exemplary scanning mirror 702 (e.g., mirror 302, 402, 502, 602, or 662). During operation, a stationary laser 701 is disposed at an angle with respect to the mirror 702 in position A at 45°. As an example, if the scanning mirror 702 moves 30° (e.g., from position A to position B or position C), then the laser beam 704 reflected by the mirror 702 moves 60° for field of view of 120°. In some practical applications, the scanning mirror 702 may move approximately 22.5° (for a 90° view) depending on the development and application.

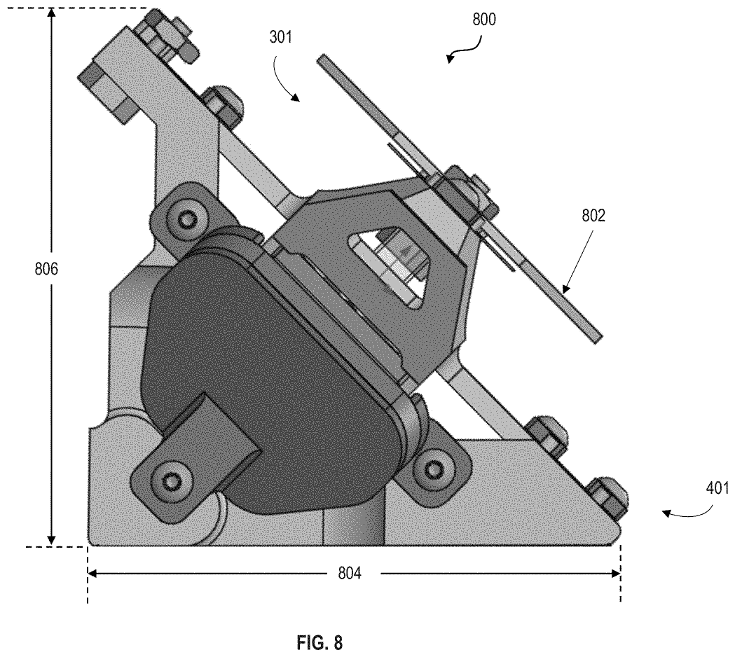

FIG. 8 illustrates a side view of a scanning mirror system 800 which includes the fast axis 301 and slow axis 401 illustrated in FIGS. 3A-4B, as well as a scan mirror 802 (e.g., scan mirror 302 or 402). One example dimension 806 of the scanning mirror system is approximately between 1 to 1.5 inches (e.g., 1.4 inches). Another example dimension 804 of the scanning mirror system is approximately between 1 to 1.5 inches (e.g., 1.387 inches (35.23 mm)). The width of the scanning mirror 802 may be, for example, between 12 mm and 30 mm.

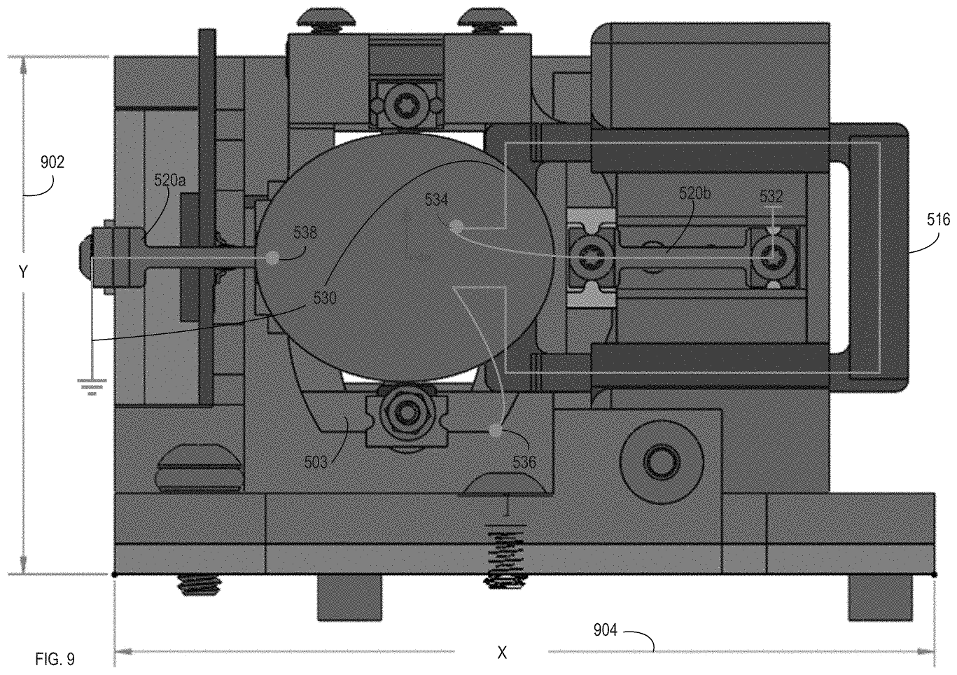

FIG. 9 illustrates a side view of the scanning mirror system 500 (of FIG. 5). A first example dimension 902 of the scanning mirror system may be approximately 1 to 1.1 inches (e.g., 1.022 inches) and the second example dimension 904 may be approximately 1.5 to 2 inches (e.g., 1.619 inches).

As discussed above, an electrical signal may be applied to (e.g., conducted through) the slow axis coil 516 to control the coil's rotation, which drives the rotation of the system's slow axis (e.g., the vertical axis in FIG. 9). Any suitable electrical circuit may be used to apply the electrical signal to the slow axis coil 516 (e.g., to provide power to the coil 516). In some embodiments, wires may be coupled to positive and negative terminals of the coil to conduct current to and from the coil. However, the scanning mechanism may subject such wires to frequent and significant vibration and/or torque, which may cause the wires to fail at a relatively high rate.

In some embodiments, to reduce reliance on loose wires, portions of the scanning system 500 may be used to conduct the electrical signal to and/or from the slow axis coil 516 (e.g., to provide electrical power to the coil 516). For example, electrical signals may be conducted to and from the slow axis coil 516 along electrical path 530. Referring to FIG. 9, a driver circuit may provide a slow axis drive signal at node 532. Node 532 may be electrically coupled to the coil 516 at node 534 via portion 520b of the slow axis flexure 520. The driver signal may propagate through the coil 516 as illustrated in FIG. 9. The coil 516 may be electrically coupled to node 536 via any suitable electrical coupling (e.g., a flexible coupling, a resilient electrical contact, etc.), and node 536 may be coupled to node 538 via any suitable electrical coupling (e.g., a wire or trace). Node 538 may be coupled to ground through portion 520a of the slow axis flexure 520.

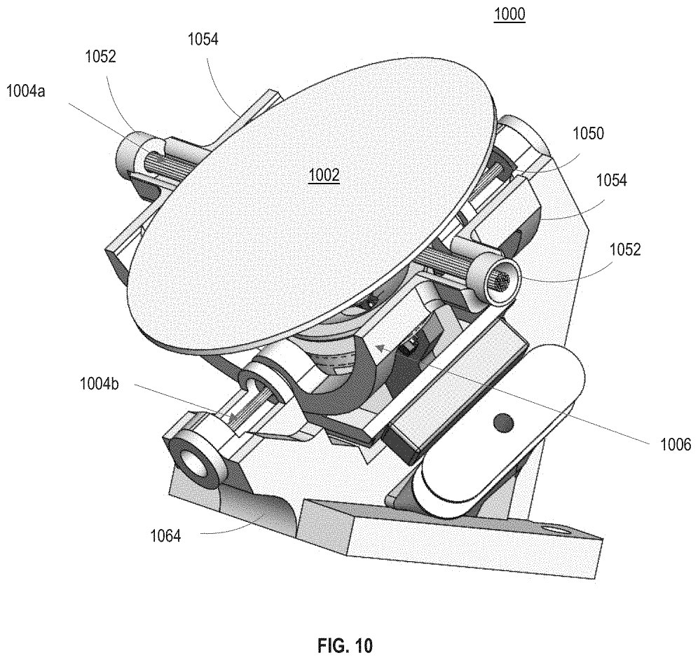

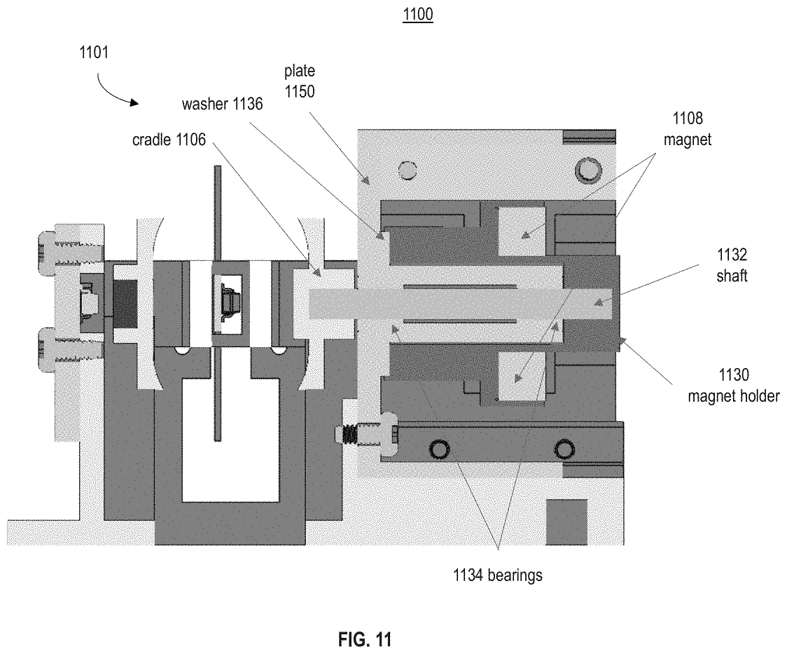

Referring to FIG. 10, in some embodiments, a scanning mirror system 1000 includes fast axis components, slow axis components, and a mirror 1002 (e.g., scanning mirror). The width (e.g., diameter) of the scanning mirror 1002 may be, for example, between 12 mm and 30 mm. In some embodiments, the fast axis components of the scanning mirror system 1000 may include and/or operate in the same manner as the fast axis components of the scanning mirror system 300, aside from the exceptions noted below. The fast axis components may include a flexure 1004b, a magnet, one or two coils (e.g., wound coils), and one or two sensors (e.g., Hall effect sensors). The fast axis can be configured to operate (e.g., oscillate) at the resonant frequency of the scanning mirror system 1000 or a portion thereof (e.g., a portion including the flexure 1004b, the mirror 1002, and the fast axis magnet).

In the example of FIG. 10, the flexure 1004b includes two or more wires. The wires may be arranged in a bundle such that the wires are substantially parallel to each other. Any suitable bundling device may be used to bundle the wires including, without limitation, a cable sleeve, a cable comb, a flexible wrap, lashing wire, etc. The flexure 1004b may be coupled to the yoke 1064 by any suitable coupling device. In some embodiments, the ends of the flexure 1004b are mechanically coupled to the yoke 1064 by bushings 1050, which may be configured to prevent the flexure 1004b from moving laterally with respect to the cradle 1006 and/or to help isolate the yoke from the vibrations of the fast axis, while still permitting the flexure 1004b to move (e.g., flex and/or twist) in response to the movement of the fast axis magnet. The magnet may be coupled (e.g., affixed) to the flexure 1004b by any suitable device, adhesive, or other coupling mechanism. As discussed above, the flexure 1004b may be designed to move (e.g., flex and/or twist) at a specific frequency depending on the mass of the mirror 1002, the mass of the fast axis magnet, the mass of the flexure 1004b, and/or the tension of the flexure 1004b. In some implementations, the flexure 1004b may have a thickness of approximately 0.004-0.008 inches. The flexure 1004b may be tensioned by any suitable tensioning mechanism.

In some embodiments, the slow axis components of the scanning mirror system 1000 may include and/or operate in the same manner as the slow axis components of the scanning mirror system 400, aside from the exceptions noted below. Still referring to FIG. 10, the slow axis components may include a flexure 1004a, one or more magnets, one or more, one or more sensors (e.g., Hall effect sensors), and a cradle 1006. In some embodiments, the slow axis is not controlled to move (e.g., oscillate) at the resonant frequency of the scanning mechanism 1000 or a portion thereof. The slow axis can be driven at a determined sequence to create a scan pattern. An example of a scan pattern is shown in FIGS. 17A-17B. The orientation of the slow axis can be 90° in relation to orientation of the fast axis. In some embodiments, the slow axis and the fast axis share one or more components. The slow axis may be controlled to synchronize with the fast axis. The slow axis may be driven at a frequency within the range of 1-30 Hz.

In the example of FIG. 10, the flexure 1004a includes two or more wires. The wires may be arranged in a bundle, and the bundled wires may be substantially parallel to each other. Any suitable bundling device may be used to bundle the wires including, without limitation, a cable sleeve, a cable comb, a flexible wrap, lashing wire, etc. The flexure 1004a may be mechanically coupled to the cradle 1006 by any suitable coupling device. In some embodiments, the ends of the flexure 1004a are mechanically coupled to the cradle 1006 by rings 1052, which may be configured to prevent the flexure 1004a from moving laterally with respect to the cradle 1006, while still permitting the flexure 1004a to move (e.g., flex and/or twist).

In some implementations, the flexure 1004a may have a thickness of approximately 0.004-0.008 inches. In some embodiments, the flexure 1004a may be tensioned by the cradle 1006. For example, the flexure 1004a may be installed in the cradle 1006 by elastically bending the ends 1054 of the cradle toward each other and placing the flexure 1004a in the cradle with the rings 1052 fixed in relation to the cradle 1006. The ends 1054 of the cradle may then be released, such that the spring force of the cradle applies tension to the flexure 1004a during operation. This technique for applying tension to the flexure may be referred to herein as “bow-string tensioning,” because the cradle may produce an elastic force that applies tension to the flexure in much the same manner as an archer's bow applies tension to the bow string. Any suitable mechanism and/or technique may be used to control the movement of the slow axis including, without limitation, the mechanisms and techniques described above.

FIGS. 11-14 illustrate some embodiments of another exemplary scanning mirror system 1100. FIG. 11 shows a slow axis 1101 of the scanning mirror system 1100, according to some embodiments. The slow axis of 1101 may be referred to herein as a “closed-loop controlled slow axis.” In some embodiments, the slow axis 1101 controls the rotation of a scanning mirror on the slow axis using a shaft 1132 and bearings 1134 rather than a flexure. The rotation of the shaft 1132 may be controlled by a magnet 1108 (e.g., a north/south magnet).

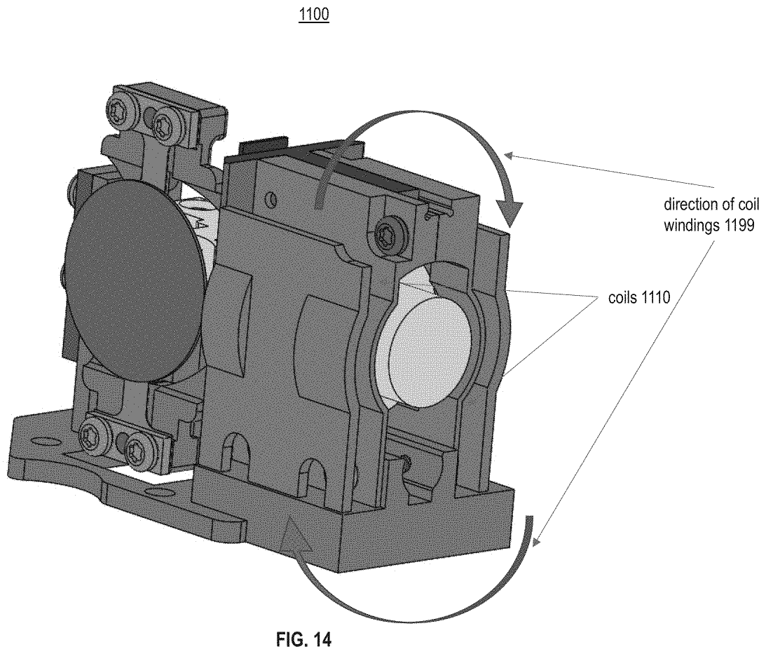

The slow axis 1101 may include a cradle 1106, a magnet 1108, two coils 1110, a sensor 1112, another magnet 1114, a magnet holder 1130, a shaft 1132, bearings 1134, a washer 1136, and a plate 1150. The coils 1110 may be air coils. The coils 1110 may be connected in series and wound in the direction 1199 indicated in FIG. 14. The magnet 1114 may be disposed at the end of the shaft 1132 adjacent to the cradle 1106, such that the magnet 1114 rotates with the shaft 1132, the cradle 1106, and the mirror. The sensor 1112 may be disposed behind the magnet 1114 or adjacent to the magnet 1114 along the second axis (e.g., on a circuit board 1152 affixed to the yoke of the scanning mirror system 1100), such that the sensor 1112 can sense the deflection of the magnet 1114 (e.g., as described above). In some embodiments, the sensor 1112 is a Hall effect sensor. One end of the shaft 1132 may be pressed into the magnet holder 1130. The other end of the shaft 1132 may be pressed into the cradle 1106. The bearings 1134 may be sleeve bearings (e.g., plastic sleeve bearings). The washer 1136 may be a thrust washer (e.g., a plastic thrust washer). The plate 1150 may be or include steel.

When the slow axis 1101 is powered (e.g., when power is applied to coils 1110), the coils may control the angular rotation of the magnet 1108, and thereby controlling the angular rotation of the shaft 1132 and the deflection of the scanning mirror in the direction corresponding to the slow axis (e.g., the vertical direction). The bearings 1134 and thrust washer 1136 may dampen the noise and/or vibration caused by the movement of the slow axis 1101.

The plate 1150 may block the magnetic fields produced by the magnet 1108 and the coils 1110, such that those magnetic fields do not disturb the magnet(s) of the fast axis or otherwise interfere with the operation of the fast axis. In addition, the plate may 1150 may provide a contact surface for the thrust washer 1136. In some embodiments, there may be an attractive magnetic force between the plate 1150 and the magnet 1108, which may attract the magnet 1108 toward the plate 1150, thereby positioning the slow axis 1101.

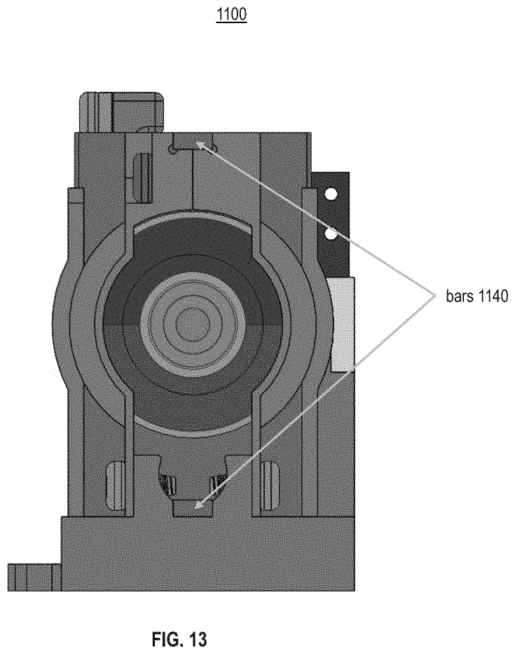

Referring to FIG. 13, in some embodiments the slow axis 1101 may include bars 1140 (e.g., steel bars), which may be positioned above and below the shaft 1132 and magnet 1108. When the coils 1110 are not powered, the magnetic forces between the magnet 1108 and the bars 1140 may return the slow axis to its center position.

In some embodiments, the slow axis 1101 may provide strong damping of oscillation via the bearings 1134 and washer 1136. The slow axis 1101 may be highly robust and/or resilient to shocks and/or vibration.

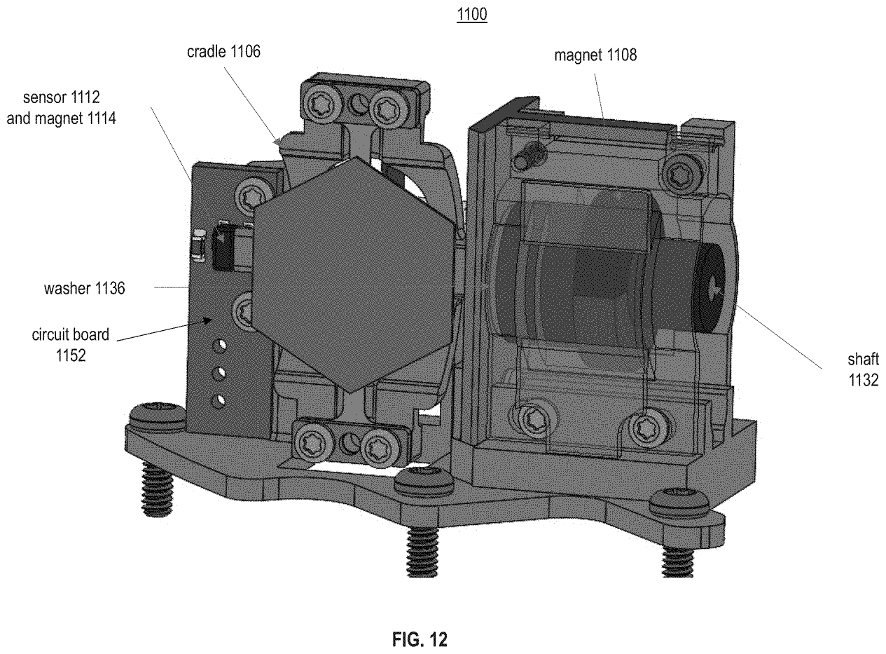

The scanning mirror system 1100 may include any suitable fast axis. FIG. 12 shows a configuration in which the fast axis of the scanning mirror system 1100 is a fast axis 301 as illustrated in FIGS. 3A-3B. FIG. 14 shows a configuration in which the fast axis of the scanning mirror system 1100 is a fast axis 601 as illustrated in FIGS. 6A-6C or a fast axis 651 as illustrated in FIG. 6D.

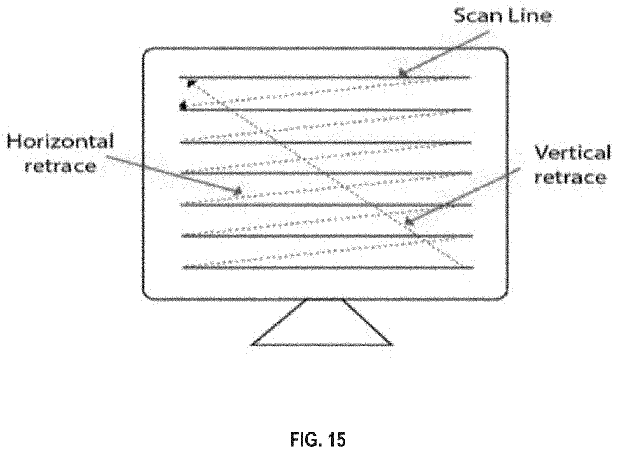

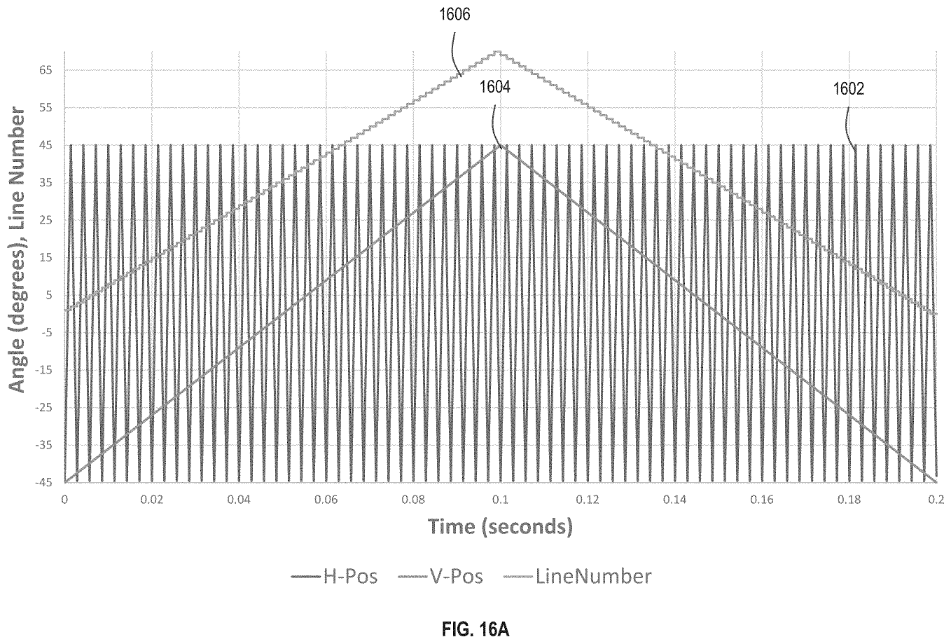

The slow axis of the scanning mirror system may be configured to follow a pattern. In some implementations, the pattern may be similar to a Raster scan (refer to https://en.wikipedia.org/wiki/Raster_scan). FIG. 15 provides an example of a Raster scan to illustrate the movement of the scanning mirror mechanism. For instance, the horizontal trace corresponds to the fast axis and the vertical trace corresponds to the slow axis. In some implementations, instead of following the vertical retrace to go back to the top as illustrated by the Raster scan, the scanning mirror system can be configured to follow a reverse scan pattern back (refer to FIGS. 17A-17B).

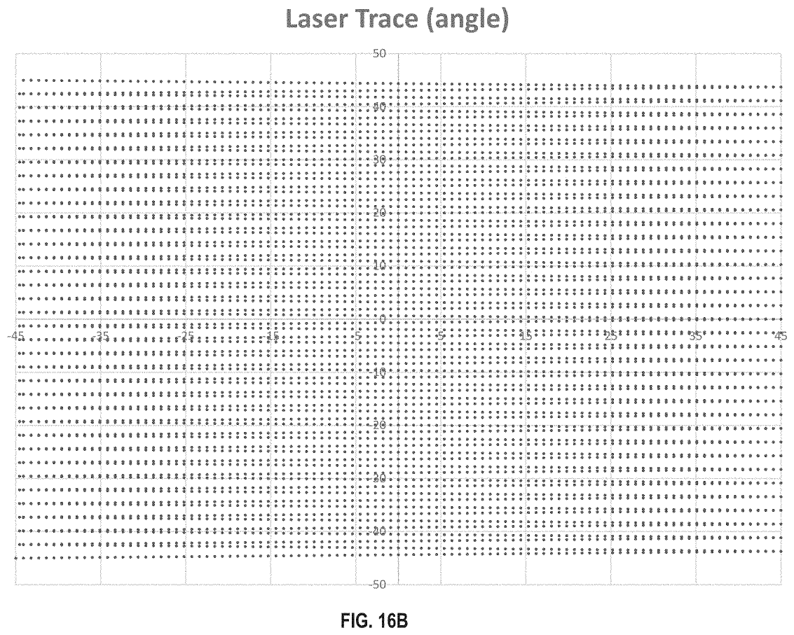

FIG. 16A is a plot of the angle of exemplary traces (described above) as a function of time. The first subplot 1602 indicates the horizontal position of the trace; the second subplot 1604 indicates the vertical position of the trace; and the third subplot indicates the line number.

FIG. 16B is a plot of the angle of an exemplary laser trace for an experimental setup of the scanning mirror system.

FIGS. 17A-17B illustrate two views of an exemplary scanning pattern for the scanning mirror.

### Further Embodiments

Some examples have been described in which a LIDAR system scans a field of view (or a portion thereof) by using a scan mirror to reflect beams of light (e.g., laser beams) emitted by a single optical emitter (e.g., a laser). In some embodiments, a scan mirror may reflect beams of light emitted by multiple optical emitters (e.g., between 2 and 64 optical emitters). In such embodiments, the scan mirror may simultaneously reflect beams of light emitted by two or more of the optical emitters into different portions of the LIDAR device's field of view. Likewise, the scan mirror may reflect return light signals to multiple optical detectors (e.g., between 2 and 64 optical detectors). In some embodiments, the scan mirror may simultaneously reflect two or more return light signals received from different portions of the LIDAR device's field of view to two or more of the optical detectors.

Some examples have been described in which there is a 1-to-1 correspondence between optical emitters and optical detectors, such that the return light corresponding to a light beam emitted by a particular emitter is detected by a particular detector. In some embodiments, the scan mirror may reflect a single return light signal (corresponding to a single emitted light beam) to two or more of the optical detectors. For example, the optical emitter may be a vertical cavity surface emitting laser (VCSEL) or other device configured to emit a line beam rather than a dot, and the return light signal corresponding to the line beam may be detected by multiple optical detectors.

Some embodiments of a scanning mirror system have been described. In some embodiments, the fast axis can deflect from 15 to 120 degrees optically. In some embodiments, the slow axis can deflect from 0 to 90 degrees optically.

In embodiments, aspects of the techniques described herein may be directed to or implemented on information handling systems/computing systems. For purposes of this disclosure, a computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data for business, scientific, control, or other purposes. For example, a computing system may be a personal computer (e.g., laptop), tablet computer, phablet, personal digital assistant (PDA), smart phone, smart watch, smart package, server (e.g., blade server or rack server), a network storage device, or any other suitable device and may vary in size, shape, performance, functionality, and price. The computing system may include random access memory (RAM), one or more processing resources such as a central processing unit (CPU) or hardware or software control logic, ROM, and/or other types of memory. Additional components of the computing system may include one or more disk drives, one or more network ports for communicating with external devices as well as various input and output (I/O) devices, such as a keyboard, a mouse, touchscreen and/or a video display. The computing system may also include one or more buses operable to transmit communications between the various hardware components.

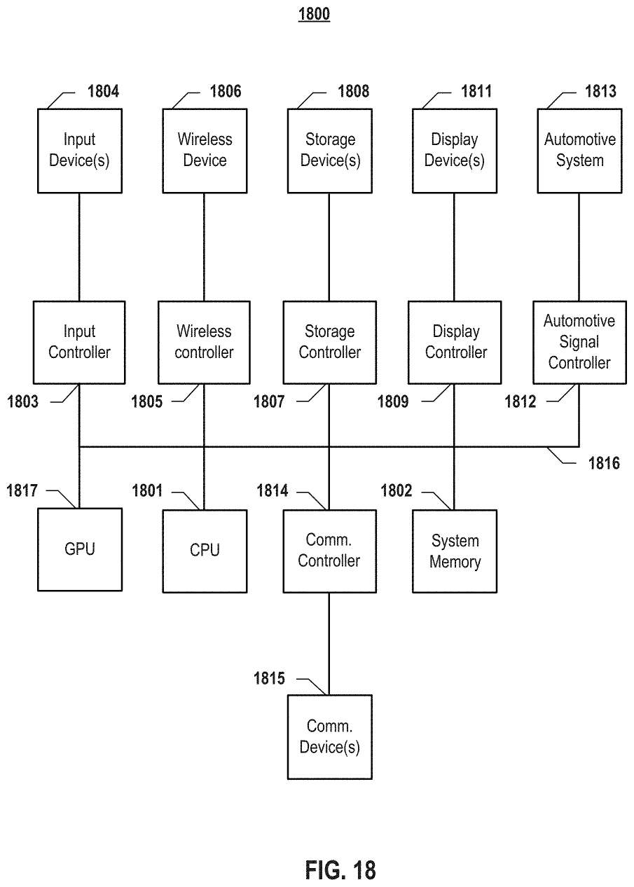

FIG. 18 depicts a simplified block diagram of a computing device/information handling system (or computing system) according to embodiments of the present disclosure. It will be understood that the functionalities shown for system 1800 may operate to support various embodiments of an information handling system—although it shall be understood that an information handling system may be differently configured and include different components.

As illustrated in FIG. 18, system 1800 includes one or more central processing units (CPU) 1801 that provides computing resources and controls the computer. CPU 1801 may be implemented with a microprocessor or the like, and may also include one or more graphics processing units (GPU) 1817 and/or a floating point coprocessor for mathematical computations. System 1800 may also include a system memory 1802, which may be in the form of random-access memory (RAM), read-only memory (ROM), or both.

A number of controllers and peripheral devices may also be provided, as shown in FIG. 18. An input controller 1803 represents an interface to various input device(s) 1804, such as a keyboard, mouse, or stylus. There may also be a scanner controller 1805, which communicates with a scanner 1806. System 1800 may also include a storage controller 1807 for interfacing with one or more storage devices 1808 each of which includes a storage medium such as magnetic tape or disk, or an optical medium that might be used to record programs of instructions for operating systems, utilities, and applications, which may include embodiments of programs that implement various aspects of the techniques described herein. Storage device(s) 1808 may also be used to store processed data or data to be processed in accordance with some embodiments. System 1800 may also include a display controller 1809 for providing an interface to a display device 1811, which may be a cathode ray tube (CRT), a thin film transistor (TFT) display, or other type of display. The computing system 1800 may also include an automotive signal controller 1812 for communicating with an automotive system 1813. A communications controller 1814 may interface with one or more communication devices 1815, which enables system 1800 to connect to remote devices through any of a variety of networks including the Internet, a cloud resource (e.g., an Ethernet cloud, an Fiber Channel over Ethernet (FCoE)/Data Center Bridging (DCB) cloud, etc.), a local area network (LAN), a wide area network (WAN), a storage area network (SAN) or through any suitable electromagnetic carrier signals including infrared signals.

In the illustrated system, all major system components may connect to a bus 1816, which may represent more than one physical bus. However, various system components may or may not be in physical proximity to one another. For example, input data and/or output data may be remotely transmitted from one physical location to another. In addition, programs that implement various aspects of some embodiments may be accessed from a remote location (e.g., a server) over a network. Such data and/or programs may be conveyed through any of a variety of machine-readable medium including, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Some embodiments may be encoded upon one or more non-transitory computer-readable media with instructions for one or more processors or processing units to cause steps to be performed. It shall be noted that the one or more non-transitory computer-readable media shall include volatile and non-volatile memory. It shall be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that some embodiments may further relate to computer products with a non-transitory, tangible computer-readable medium that have computer code thereon for performing various computer-implemented operations. The media and computer code may be those specially designed and constructed for the purposes of the techniques described herein, or they may be of the kind known or available to those having skill in the relevant arts. Examples of tangible computer-readable media include, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Examples of computer code include machine code, such as produced by a compiler, and files containing higher level code that are executed by a computer using an interpreter. Some embodiments may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the techniques described herein. One skilled in the art will also recognize that a number of the elements described above may be physically and/or functionally separated into sub-modules or combined together.

While this specification contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous. Other steps or stages may be provided, or steps or stages may be eliminated, from the described processes. Accordingly, other implementations are within the scope of the following claims.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A scanner of a LiDAR system, the scanner comprising:
a mirror having a reflective surface configured to redirect a light signal emitted by an optical emitter;
a first axis scanning system configured to rotate the reflective surface of the mirror about a first axis and with respect to the optical emitter, that controls a first angle of emission of the light signal from the LiDAR system into a field of view of the LiDAR system; and
a second axis scanning system configured to rotate the reflective surface of the mirror about a second axis and with respect to the optical emitter, that controls a second angle of emission of the light signal from the LiDAR system into the field of view of the LiDAR system,
wherein the first axis scanning mechanism is configured to rotate the reflective surface of the mirror at least 45 degrees about the first axis.

2. The scanner of claim 1, wherein the optical emitter comprises a laser.

3. The scanner of claim 1, wherein the first angle of emission is a horizontal angle of emission.

4. The scanner of claim 3, wherein rotating the reflective surface of the mirror about the first axis changes a horizontal angle of incidence between (1) the reflective surface and (2) an optical path from the optical emitter to the reflective surface.

5. The scanner of claim 3, wherein the second angle of emission is a vertical angle of emission.

6. The scanner of claim 5, wherein rotating the reflective surface of the mirror about the second axis changes a vertical angle of incidence between (1) the reflective surface and (2) an optical path from the optical emitter to the reflective surface.

7. The scanner of claim 3, wherein rotating the reflective surface of the mirror about the first axis changes a horizontal angle of incidence between (1) the reflective surface and (2) an optical path from the optical emitter to the reflective surface.

8. The scanner of claim 1, wherein rotating the reflective surface of the mirror 45 degrees about the first axis scans a 90 degree field of view.

9. The scanner of claim 1, wherein the second axis scanning mechanism is configured to rotate the reflective surface of the mirror at least 45 degrees about the second axis, thereby scanning a 90 degree field of view.

10. The scanner of claim 1, wherein the mirror has a diameter between 12 mm and 30 mm, or the mirror has a length between 12 mm and 30 mm and a width between 12 mm and 30 mm.

11. The scanner of claim 1, wherein the first axis is orthogonal to the second axis.

12. The scanner of claim 1, wherein the first axis scanning system comprises:
first mobile components including a first flexure affixed to a back of the mirror and a first magnet affixed to the first flexure;
two first field coils disposed proximate to the first magnet; and
a first magnetic field sensor disposed between the first field coils.

13. The scanner of claim 11, wherein the first flexure comprises a metal plate.

14. The scanner of claim 11, wherein the first flexure comprises a bundle of wires.

15. The scanner of claim 13, further comprising a yoke, wherein first and second ends of the first flexure are coupled to the yoke by respective bushings.

16. The scanner of claim 11, wherein the first flexure is configured to twist at a frequency determined by a mass of the mirror, a mass of the first magnet, and a tension of the first flexure.

17. The scanner of claim 11, where in the first magnetic field sensor is a Hall effect sensor.

18. The scanner of claim 11, further comprising a controller, wherein the first field coils face each other and the controller is configured to drive the first field coils in series by alternately activating and deactivating the first field coils, with a particular one of the first field coils being activated when the other first field coil is deactivated, and the particular first field coil being deactivated when the other first field coil is activated.

19. The scanner of claim 18, wherein a frequency of alternating activation of the first field coils is substantially equal to a resonant frequency of a structure including the mirror and the first mobile components.

20. The scanner of claim 19, wherein the resonant frequency is between 5 Hz and 1 kHz.

21. The scanner of claim 19, wherein the alternating activation of the first field coils causes the first magnet and the mirror to rotate about the first axis.

22. The scanner of claim 12, wherein the second axis scanning system comprises:
second mobile components including a cradle, a first portion of a second flexure connected to a first end of the cradle, a second portion of the second flexure connected to a second end of the cradle, and one or more second magnets affixed to the cradle, wherein the mirror is disposed in the cradle;
one or more second field coils; and
one or more second magnetic field sensors.

23. The scanner of claim 22, further comprising a yoke, wherein the first portion of the second flexure connects the first end of the cradle to the yoke along the second axis, and wherein the second portion of the second flexure connects the second end of the cradle to the yoke along the second axis.

24. The scanner of claim 23, where each of the first and second portions of the second flexure comprises spring steel or a bundle of wires.

25. The scanner of claim 22, wherein the one or more second magnetic field sensors comprise two Hall effect sensors configured to generate a differential signal indicating a strength of a magnetic field generated by the one or more second magnets.

26. The scanner of claim 22, wherein the one or more second field coils comprise two second field coils disposed proximate to opposite sides of the cradle, and wherein the one or more second magnets comprise two second magnets affixed to the opposite sides of the cradle.

27. The scanner of claim 26, further comprising a controller configured to drive the two second field coils in series by alternately activating and deactivating the two second field coils, with a particular one of the second field coils being activated when the other second field coil is deactivated, and the particular second field coil being deactivated when the other second field coil is activated.

28. The scanner of claim 27, wherein the alternating activation of the second field coils causes the cradle, the two or more second magnets, and the mirror to rotate about the second axis with a rotation frequency between 0.01 Hz and 30 Hz.

29. The scanner of claim 22, wherein the one or more second field coils comprise a single second field coil disposed proximate to a side of the cradle, and wherein the one or more second magnets comprise a single magnet affixed to the side of the cradle.

30. The scanner of claim 29, further comprising a controller configured to drive the single second field coil with an alternating current to cause the cradle, the mirror, and the single magnet to rotate about the second axis with a rotation frequency between 0.01 Hz and 30 Hz.

31. The scanner of claim 1, wherein the second axis scanning system comprises:
second mobile components including a cradle, a first portion of a second flexure connected to a first end of the cradle, a second portion of the second flexure connected to a second end of the cradle, and a rotatable coil coupled to the cradle, wherein the mirror is disposed in the cradle;
one or more second magnets; and
a second magnetic field sensor.

32. The scanner of claim 31, wherein the second magnetic field sensor comprises a magnet.

33. The scanner of claim 32, wherein the each of the first and second portions of the second flexure comprises beryllium copper or a bundle of wires.

34. The scanner of claim 31, further comprising a yoke, wherein the first portion of the second flexure connects the first end of the cradle to the yoke along the second axis, and wherein the second portion of the second flexure connects the second end of the cradle to the yoke along the second axis.

35. The scanner of claim 31, further comprising a controller configured to apply an electrical signal to the rotatable coil to control a rotation of the rotatable coil, the cradle, and the mirror about the second axis.

36. The scanner of claim 35, wherein the controller is configured to apply the electrical signal to the rotatable coil via an electrical path comprising the first and second portions of the second flexure.

37. The scanner of claim 31, wherein the first axis scanning system comprises:
first mobile components including a first flexure affixed to a back of the mirror and a first magnet affixed to the first flexure;
a first field coil disposed proximate to the first magnet; and
a first magnetic field sensor disposed proximate to the first field coil.

38. The scanner of claim 37, wherein the flexure comprises spring steel or a bundle of wires.

39. The scanner of claim 37, wherein at least a portion of the first magnetic field sensor is disposed above the first field coil.

40. The scanner of claim 39, further comprising a controller configured to determine an angle of rotation of the mirror with respect to the first axis using the first magnetic field sensor.

41. The scanner of claim 40, wherein determining the angle of rotation of the mirror with respect to the first axis comprises:
deactivating the first field coil;
controlling the first magnetic field sensor to generate a signal indicative of a magnitude of a magnetic field generated by the first magnet;
determining the angle of rotation of the mirror with respect to the first axis based on the signal indicative of the magnitude of the magnetic field; and
reactivating the first field coil.

42. The scanner of claim 40, wherein determining the angle of rotation of the mirror with respect to the first axis comprises:
controlling the first magnetic field sensor to generate a signal indicative of a magnitude of a magnetic field generated by the first magnet and the first field coil;
determining a magnitude of a magnetic field generated by the first magnet based on (1) the signal indicative of the magnitude of the magnetic field generated by the first magnet and the first field coil, and (2) an estimate of a magnitude of the magnetic field generated by the first field coil.

43. The scanner of claim 37, wherein the first magnetic field sensor is disposed within the first field coil.

44. The scanner of claim 43, further comprising a controller configured to determine an angle of rotation of the mirror with respect to the first axis using the first magnetic field sensor by:
while the first field coil is active, controlling the first magnetic field sensor to generate a signal indicative of a magnitude of a magnetic field generated by the first magnet; and
determining the angle of rotation of the mirror with respect to the first axis based on the signal indicative of the magnitude of the magnetic field.

45. The scanner of claim 1, wherein the second axis scanning system comprises:
a cradle, wherein the mirror is disposed in the cradle;
a magnet holder;
a shaft having a first end and a second end, wherein a portion of the shaft proximate to the first end is pressed into the magnet holder and a portion of the shaft proximate to the second end is pressed into the cradle;
a second magnet held by the magnet holder and disposed circumferentially around the shaft; and
a plurality of second coils disposed around the first portion of the shaft.

46. The scanner of claim 45, further comprising a controller configured to control an angular rotation of the second magnet, the shaft, the cradle, and the mirror with respect to the second axis.

47. The scanner of claim 46, wherein the controller is configured to control the angular rotation by applying one or more electrical signals to the plurality of second coils.

48. The scanner of claim 45, wherein the second magnet is a permanent magnet.

49. The scanner of claim 45, further comprising a yoke, wherein the second axis scanning system further comprises:
a third magnet affixed to the shaft proximate to the second end of the shaft; and
a magnetic field sensor affixed to the yoke and disposed behind the second end of the shaft, wherein the magnetic field sensor is configured to generate a signal indicative of a magnitude of a magnetic field generated by the third magnet.

50. The scanner of claim 45, wherein the second axis scanning system further comprises:
one or more sleeve bearings disposed circumferentially around the shaft;
a plate disposed between the magnet holder and the cradle; and
a washer disposed between the plate and the magnet holder,
wherein the shaft extends through an opening in the washer and an opening in the plate.

51. The scanner of claim 50, wherein the plate is configured to shield the third magnet and the first axis scanning system from a magnetic field generated by the second magnet.

52. The scanner of claim 50, wherein the sleeve bearings and the washer are configured to dampen an oscillation of the second axis scanning system.

53. The scanner of claim 45, wherein the second axis scanning system further comprises:
a first bar comprising ferromagnetic material and disposed above the first end of the shaft, wherein the first bar exerts a first magnetic force on the second magnet; and
a second bar comprising ferromagnetic material and disposed below the first end of the shaft, wherein the second bar exerts a second magnetic force on the second magnet.

54. The scanner of claim 53, wherein the first magnetic force and the second magnetic force operate to return the shaft to a center angular position when the second coils are deactivated.

55. The scanner of claim 45, wherein the first axis scanning system comprises:
first mobile components including a first flexure affixed to a back of the mirror and a first magnet affixed to the first flexure;
two first field coils disposed proximate to the first magnet; and
a first magnetic field sensor disposed between the first field coils.

56. The scanner of claim 55, further comprising a yoke, wherein first and second ends of the first flexure are coupled to the yoke.

57. The scanner of claim 55, further comprising a controller, wherein the first field coils face each other and the controller is configured to drive the first field coils in series by alternately activating and deactivating the first field coils, with a particular one of the first field coils being activated when the other first field coil is deactivated, and the particular first field coil being deactivated when the other first field coil is activated.

58. The scanner of claim 57, wherein the alternating activation of the first field coils causes the first magnet and the mirror to rotate about the first axis.

59. The scanner of claim 45, wherein the first axis scanning system comprises:
first mobile components including a first flexure affixed to a back of the mirror and a first magnet affixed to the first flexure;
a first field coil disposed proximate to the first magnet; and
a first magnetic field sensor disposed proximate to the first field coil.

60. The scanner of claim 59, wherein at least a portion of the first magnetic field sensor is disposed above the first field coil.

61. The scanner of claim 60, further comprising a controller configured to determine an angle of rotation of the mirror with respect to the first axis using the first magnetic field sensor by:
deactivating the first field coil;
controlling the first magnetic field sensor to generate a signal indicative of a magnitude of a magnetic field generated by the first magnet;
determining the angle of rotation of the mirror with respect to the first axis based on the signal indicative of the magnitude of the magnetic field; and
reactivating the first field coil.

62. The scanner of claim 60, further comprising a controller configured to determine an angle of rotation of the mirror with respect to the first axis using the first magnetic field sensor by:
controlling the first magnetic field sensor to generate a signal indicative of a magnitude of a magnetic field generated by the first magnet and the first field coil;
determining a magnitude of a magnetic field generated by the first magnet based on (1) the signal indicative of the magnitude of the magnetic field generated by the first magnet and the first field coil, and (2) an estimate of a magnitude of the magnetic field generated by the first field coil.

63. The scanner of claim 59, wherein the first magnetic field sensor is disposed within the first field coil.

64. The scanner of claim 63, further comprising a controller configured to determine an angle of rotation of the mirror with respect to the first axis using the first magnetic field sensor by:
while the first field coil is active, controlling the first magnetic field sensor to generate a signal indicative of a magnitude of a magnetic field generated by the first magnet; and
determining the angle of rotation of the mirror with respect to the first axis based on the signal indicative of the magnitude of the magnetic field.

65. A scanning method for a LiDAR system, the method comprising:
emitting, by an optical emitter, a light signal;
rotating, by a first axis scanning system, a reflective surface of a mirror about a first axis and with respect to the optical emitter, thereby controlling a first angle of emission of the light signal from the LiDAR system into a field of view of the LiDAR system;
rotating, by a second axis scanning system, the reflective surface of the mirror about a second axis and with respect to the optical emitter, thereby controlling a second angle of emission of the light signal from the LiDAR system into the field of view of the LiDAR system,
wherein the first axis scanning mechanism rotates the reflective surface of the mirror at least 45 degrees about the first axis.

66. The method of claim 65, wherein rotating the reflective surface of the mirror about the first axis changes a first angle of incidence between (1) the reflective surface and (2) an optical path from the optical emitter to the reflective surface, and wherein rotating the reflective surface of the mirror about the second axis changes a second angle of incidence between (1) the reflective surface and (2) an optical path from the optical emitter to the reflective surface.

67. The method of claim 66, wherein rotating the reflective surface of the mirror 45 degrees about the first axis scans a 90 degree field of view.

68. The method of claim 65, wherein the second axis scanning mechanism rotates the reflective surface of the mirror at least 45 degrees about the second axis, thereby scanning a 90 degree field of view.

69. The method of claim 65, wherein the mirror has a diameter between 12 mm and 30 mm.

70. The method of claim 65, wherein the mirror has a length between 12 mm and 30 mm and a width between 12 mm and 30 mm.

71. The method of claim 65, wherein the first axis is orthogonal to the second axis.

72. The method of claim 65, wherein:
the first axis scanning system includes a first flexure affixed to a back of the mirror, a first magnet affixed to the first flexure, and two first field coils disposed proximate to the first magnet, and
the method further comprises, with a controller, controlling the first magnet and the mirror to rotate about the first axis by alternately activating and deactivating two first field coils of the first axis scanning system.

73. The method of claim 72, wherein a frequency of alternating activation of the first field coils is substantially equal to a resonant frequency of the mirror, the first flexure, and the first magnet.

74. The method of claim 73, wherein the resonant frequency is between 5 Hz and 1 kHz.

75. The method of claim 65, wherein:
the first axis scanning system includes a first flexure affixed to a back of the mirror, a first magnet affixed to the first flexure, a first field coil disposed proximate to the first magnet, and a first magnetic field sensor disposed proximate to the first field coil, and
the method further comprises, with a controller, controlling the first magnet and the mirror to rotate about the first axis by providing electrical signals to the first field coil.

76. The method of claim 75, wherein at least a portion of the first magnetic field sensor is disposed above the first field coil.

77. The method of claim 76, further comprising determining, with the controller, an angle of rotation of the mirror with respect to the first axis using the first magnetic field sensor by:
deactivating the first field coil;
controlling the first magnetic field sensor to generate a signal indicative of a magnitude of a magnetic field generated by the first magnet;
determining the angle of rotation of the mirror with respect to the first axis based on the signal indicative of the magnitude of the magnetic field; and
reactivating the first field coil.

78. The method of claim 76, further comprising determining, with the controller, an angle of rotation of the mirror with respect to the first axis by:
controlling the first magnetic field sensor to generate a signal indicative of a magnitude of a magnetic field generated by the first magnet and the first field coil;
determining a magnitude of a magnetic field generated by the first magnet based on (1) the signal indicative of the magnitude of the magnetic field generated by the first magnet and the first field coil, and (2) an estimate of a magnitude of the magnetic field generated by the first field coil.

79. The method of claim 75, wherein the first magnetic field sensor is disposed within the first field coil.

80. The method of claim 79, further comprising determining, with the controller, an angle of rotation of the mirror with respect to the first axis using the first magnetic field sensor by:
while the first field coil is active, controlling the first magnetic field sensor to generate a signal indicative of a magnitude of a magnetic field generated by the first magnet; and
determining the angle of rotation of the mirror with respect to the first axis based on the signal indicative of the magnitude of the magnetic field.

81. The method of claim 65, wherein:
the second axis scanning system comprises a cradle in which the mirror is disposed, a second flexure connecting first and second ends of the cradle along the second axis to a yoke, one or more second magnets affixed to the cradle, one or more second field coils, and one or more second magnetic field sensors, and
the method further includes generating, using the one or more second magnetic field sensors, a differential signal indicating a strength of a magnetic field generated by the one or more second magnets.

82. The method of claim 81, wherein:
the one or more second field coils comprise two second field coils disposed proximate to opposite sides of the cradle,
the one or more second magnets comprise two second magnets affixed to the opposite sides of the cradle, and
the method further includes, with a controller, rotating the cradle, the two or more second magnets, and the mirror about the second axis with a rotation frequency between 0.01 Hz and 30 Hz.

83. The method of claim 82, wherein rotating the cradle, the two or more second magnets, and the mirror about the second axis comprises driving the two second field coils in series by alternately activating and deactivating the two second field coils, with a particular one of the second field coils being activated when the other second field coil is deactivated, and the particular second field coil being deactivated when the other second field coil is activated.

84. The method of claim 81, wherein:
the one or more second field coils comprise a single second field coil disposed proximate to a side of the cradle,
the one or more second magnets comprise a single magnet affixed to the side of the cradle, and
the method further includes, with a controller, rotating the cradle, the single second magnet, and the mirror about the second axis with a rotation frequency between 0.01 and 30 Hz.

85. The method of claim 84, wherein rotating the cradle, the single second magnet, and the mirror about the second axis comprises driving the single second field coil with an alternating current having a frequency between 0.01 and 30 Hz.

86. The method of claim 65, wherein:
the second axis scanning system comprises a cradle in which the mirror is disposed, a second flexure connecting first and second ends of the cradle along the second axis to a yoke, a rotatable coil coupled to the cradle, one or more second magnets, and a second magnetic field sensor, and
the method further comprises, with a controller, applying an electrical signal to the rotatable coil to control a rotation of the rotatable coil, the cradle, and the mirror about the second axis.

87. The method of claim 86, wherein the electrical signal is applied to the rotatable coil via an electrical path comprising the second flexure.

88. The method of claim 87, wherein the electrical signal comprises an AC current with a frequency between 0.01 and 30 Hz.

89. The method of claim 65, wherein:
the second axis scanning system comprises a cradle in which the mirror is disposed, a magnet holder, a shaft having a first end and a second end, a second magnet held by the magnet holder and disposed circumferentially around the shaft, and a plurality of second coils disposed around the first portion of the shaft, wherein a portion of the shaft proximate to the first end is pressed into the magnet holder and a portion of the shaft proximate to the second end is pressed into the cradle, and
the method further includes, with a controller, applying one or more electrical signals to the plurality of second coils to rotate the second magnet, the shaft, the cradle, and the mirror with respect to the second axis.

90. The method of claim 89, wherein:
the second axis scanning system further comprises a third magnet affixed to the shaft proximate to the second end of the shaft and a magnetic field sensor affixed to the yoke and disposed proximate to the second end of the shaft, and
the method further includes generating, with the magnetic field sensor, a signal indicative of a magnitude of a magnetic field generated by the third magnet.

91. The method of claim 89, wherein:
the second axis scanning system further comprises a first bar comprising ferromagnetic material and disposed above the first end of the shaft, and a second bar comprising ferromagnetic material and disposed below the first end of the shaft, wherein the first and second bars exert first and second magnetic forces, respectively, on the second magnet, and
wherein the first magnetic force and the second magnetic force operate to return the shaft to a center angular position when the second coils are deactivated.
